(19) United States
(12) Patent Application Publication
(10) Pub. No.: US 2012/0176150 A1
(43) Pub. Date: Jul. 12, 2012

(54) MEASURING EQUIPMENT FOR PROBE-EFFECT CANCELLATION AND METHOD THEREOF

(76) Inventors: Hsing-Chou Hsu, Tainan County (TW); Sheng-Fan Yang, Tainan County (TW); Wei-Da Guo, Tainan County (TW); Jui-Ni Lee, Tainan County (TW); Tung-Yang Chen, Tainan County (TW)

(21) Appl. No.: 12/987,969

(22) Filed: Jan. 10, 2011

(51) Int. Cl. G01R 31/20

(52) U.S. Cl. 324/754.03

(57) ABSTRACT

A measuring equipment, such as a vector network analyzer, is provided. The measuring equipment includes a first port and a second port, a probe connected to the first port, an antenna connected to the second port, and a test board corresponding to a type of a device-under-test. A probe-effect is obtained by measuring the test board via the probe and the antenna.

### BACKGROUND OF THE INVENTION

1. Field of the Invention

The present invention relates to a measuring equipment, and more particularly, to a measuring equipment for probe-effect cancellation and a method thereof.

2. Description of the Prior Art

Since time-domain measurements cannot provide enough information about frequency-dependent interferences, therefore, frequency-domain measurements utilizing a measuring equipment, such as a vector network analyzer (VNA), have been developed recently, which track back the leakage path of unwanted signals by measuring transmission responses in the frequency domain.

Traditionally, a contact measurement is usually adopted on a vector network analyzer for measuring noise of a test device. However, extra testing points or extra equipments are required by using this conventional method. For this reason, a non-contact measurement may be adopted on the vector network analyzer for replacing the contact measurement in order to avoid permanent destructive damages. However, the near-field probe effect(s) will affect the measured result of the test device.

Hence, how to calibrate the vector network analyzer in order to achieve a more precise measured result, especially when a non-contact measurement is adopted, has become an important topic of this field.

### SUMMARY OF THE INVENTION

It is one of the objectives of the present invention to provide a measuring equipment and a method for probe-effect cancellation of a measuring equipment, to solve the abovementioned problems.

According to one aspect of the present invention, an exemplary measuring equipment is provided. The measuring equipment may be implemented by a vector network analyzer. The measuring equipment includes a first port and a second port, a probe connected to the first port, an antenna connected to the second port, and a test board corresponding to a type of a device-under-test. A probe-effect is obtained by measuring the test board via the probe and the antenna.

In one embodiment, the test board comprises a transmission line without termination if the device-under-test is of the capacitive type.

In another embodiment, when the test board comprises a transmission line with termination if the device-under-test is of the resistive type.

In still another embodiment, the test board comprises a transmission lines and a decoupling capacitor forming a current loop, if the device-under-test is of the power/ground type.

According to another aspect of the present invention, an exemplary method for probe-effect cancellation of a measuring equipment is provided. The measuring equipment has a first port and a second port for measuring a device-under-test. The exemplary method includes the steps of: connecting a probe to the first port, and connecting an antenna to the second port; determining a type of the device-under-test; selecting a test board according to the type of the device-under-test; and obtaining a probe-effect by measuring the test board via the probe and the antenna.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1A is a diagram illustrating a contact measurement on a vector network analyzer.

FIG. 1B is a diagram illustrating a non-contact measurement on a vector network analyzer using two probes.

FIG. 1C is a diagram illustrating a non-contact measurement on a vector network analyzer using a probe and an antenna.

FIG. 2 is a diagram illustrating a calibrating system for calibrating a vector network analyzer according to a first embodiment of the present invention.

FIG. 3 is a diagram illustrating a calibrating system for calibrating a vector network analyzer according to a second embodiment of the present invention.

FIG. 4 is a diagram illustrating a calibrating system for calibrating a vector network analyzer according to a third embodiment of the present invention.

FIG. 5 is a flowchart illustrating a calibrating method for calibrating a vector network analyzer according to an exemplary embodiment of the present invention.

FIG. 6 is a flowchart illustrating a calibrating method for calibrating a vector network analyzer according to another exemplary embodiment of the present invention.

### DETAILED DESCRIPTION

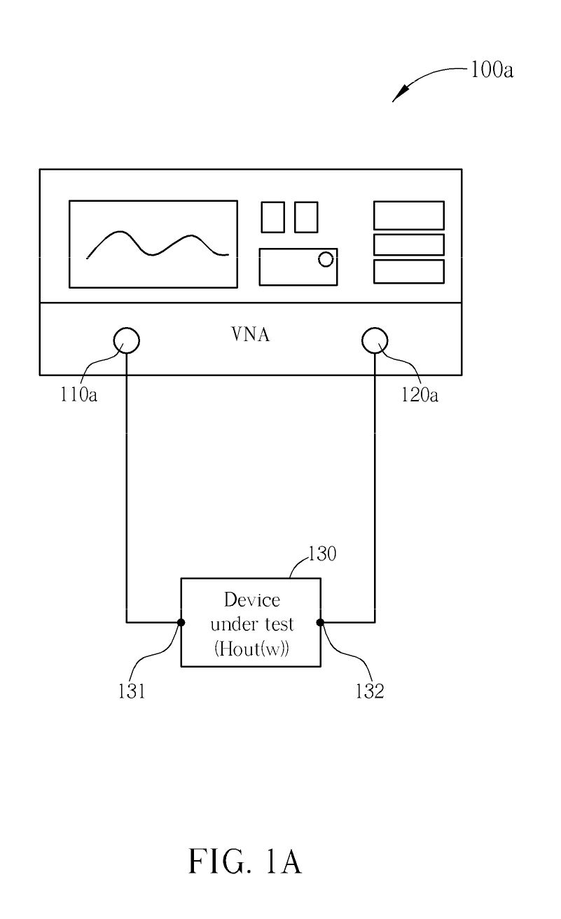

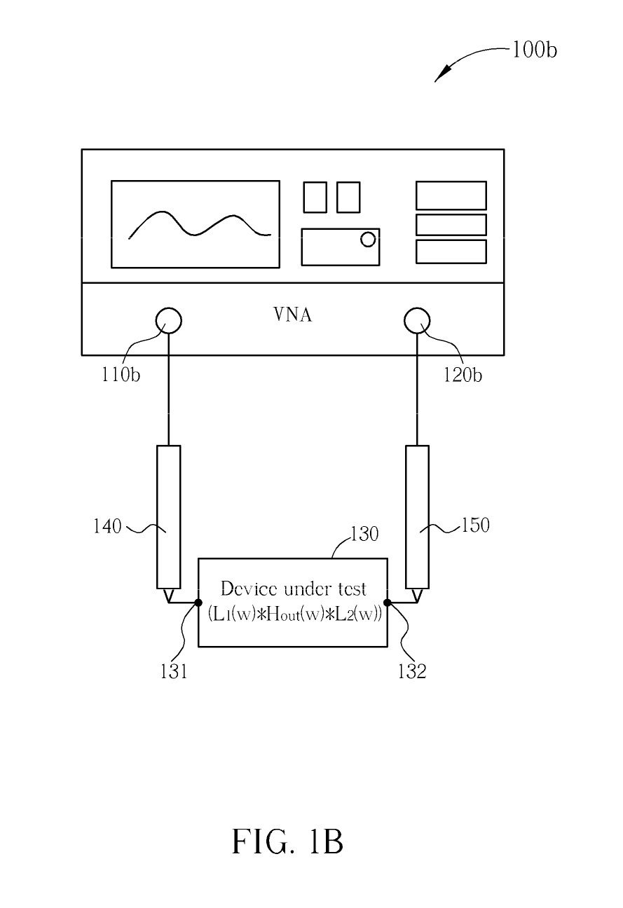

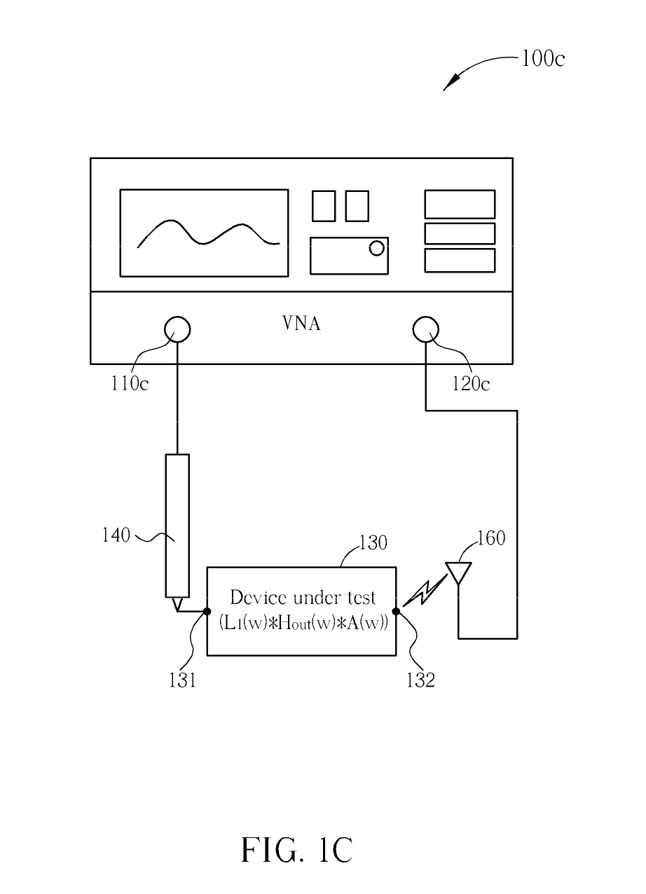

First, in order to make the specification of the present invention easy to understand, a brief description of the VNA-measurement-based transfer function technique is given as below. FIG. 1A, FIG. 1B, and FIG. 1C depict the VNA-measurement-based transfer function technique, which includes three different types of measurement configurations. FIG. 1A shows a contact measurement on a vector network analyzer 100a. The vector network analyzer 100 a has a first port 110a and a second port 120a, wherein the first port 110a is directly coupled to a first terminal 131 of a device under test 130 and the second port 120a is directly coupled to a second terminal 132 of the device under test 130 through coaxial cables and SMA connectors. Transfer function H_{DUT}(ω) represents the frequency response of the test signal flowing through the path in the device under test 130.

The non-contact measurement on a vector network analyzer 100b by using two probes is shown in FIG. 1B. The vector network analyzer 100b has a first port 110b and a second port 120b. A first probe 140 connected to the first port 110b emits a test signal and induces a small induced current that flows into the device under test 130. A second probe 150 connected to the second port 120b of the vector network analyzer 100b thus can receive the electromagnetic radiation emitted by the induced current. Furthermore, the total measured transfer function can be expressed as:

Hb(ω)=L1(ω)*H_{DUT}(ω)*L2(ω) (1);

where the symbol L1(ω) represents the frequency-domain near-field probe-effect corresponding to the first probe 140, and the symbol L2(ω) represents the frequency-domain near-field probe-effect corresponding to the second probe 150.

Another non-contact measurement on a vector network analyzer 100c by using a probe and antenna is shown in FIG. 1C. In this embodiment, the second probe 150 in FIG. 1b can be replaced with an antenna 160. Therefore, the total measured transfer function can be modified and expressed as:

Hb(ω)=L(ω)*H_{DUT}(ω)*A(ω) (2);

where the symbol A(ω) represents the antenna factor with respect to the radiation pattern of the antenna 160.

The measured result Hb(ω) includes the probe-effect L(ω) of the first probe, which should be cancelled in order to get the more accurate transfer function H_{DUT}(ω) of the device under test.

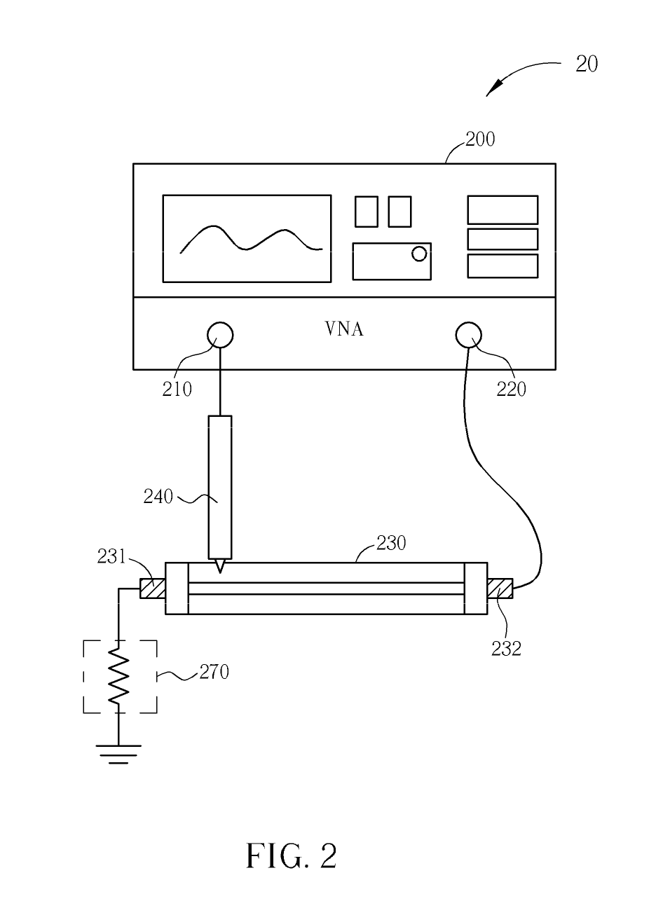

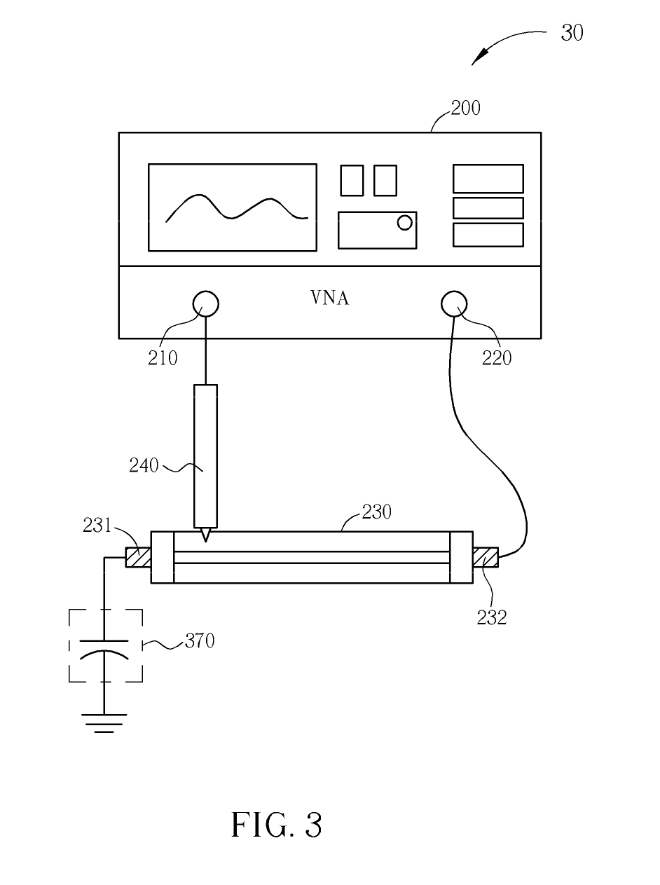

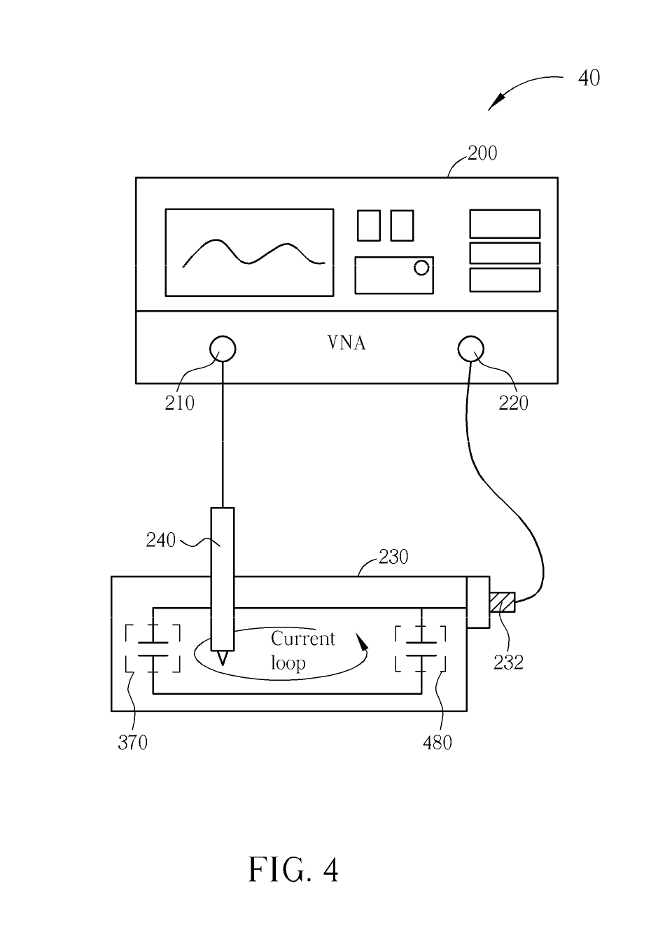

In order to cancel the probe-effect L(ω), the method, according to an embodiment of the invention, to obtain the near-field probe-effect L(ω) can be demonstrated in FIG. 2, FIG. 3, and FIG. 4. The device under test (DUT) can be classified into different types, for example, a resistive type, a capacitive type, and a power/ground type, each corresponds to a different probe-effect. In a preliminary phase, the probe-effect L(ω) is obtained by using a test board based on the type of the DUT, and in a measurement phase, the DUT is measured to obtain Hb(ω). The probe-effect L(ω) is then cancelled from the obtained Hb(ω) to get H_{DUT}(ω).

Please refer to FIG. 2, which is a diagram illustrating a calibrating system 20 for calibrating a measuring equipment 200, such as a vector network analyzer, by a resistive-type test board 230. As shown in FIG. 2, the calibrating system 20 includes a measuring equipment 200, a test board 230, a probe 240. The measuring equipment 200 has a first port 210 connected to the probe 240 and a second port 220. The test board 230 has a first terminal 231, a second terminal 232, a transmission line 233 and a termination 270, The termination 270 is a first passive component coupled to the first terminal 231 of the test board 230. Please note that the measuring equipment 200 performs a probe test upon the test board 230 via the probe 240, such that a probe effect related to the probe 240 can be obtained by measuring the test board 230 via the probe 240. Moreover, the measuring equipment 200 performs a measuring test upon the test board 230, such that a measured result related to the test board 230 can be obtained. Finally, the measuring equipment 200 subtracts the probe effect related to the probe 240 from the measured result related to the test board 230, such that characteristics related to the test board 230 can be obtained.

In this embodiment, when the test board 230 includes a transmission line with terminations, the first passive component 270 may be implemented by a resistive component. Please note that the calibrating system 20 having the resistive component to implement the first passive component 270 is especially suitable for the test signal with a resistive signal transmission. In addition, an impedance of the resistive component should match with an impedance of the transmission line, such as 50 ohms.

FIG. 3 is a diagram illustrating a calibrating system 30 for calibrating the measuring equipment 200 according to a second embodiment of the present invention. The architecture of the calibrating system 30 is similar to that of the calibrating system 20 shown in FIG. 2, and the major difference between them is that: when t the test board 230 includes a transmission line without terminations, the first passive component 370 of the calibrating system 30 is implemented by a capacitive component instead of a resistive component. Please note that the calibrating system 30 having the capacitive component to implement the first passive component 370 is especially suitable for the test signal with a capacitive signal transmission, such as transistor-transistor logic (TTL) transmission.

FIG. 4 is a diagram illustrating a calibrating system 40 for calibrating the measuring equipment 200 according to a third embodiment of the present invention. The architecture of the calibrating system 40 is similar to that of the calibrating system 30 shown in FIG. 3, and the difference between them is that the calibrating system 40 further includes a second passive component 480, wherein when the checking result CR of the checking unit 290 indicates that the test board 230 is a power line or a ground line, the second passive component 480 is coupled to the second terminal 232 of the test board 230. Be noted that the first passive component 370, the second passive component 480, and the test board 230 form a current loop. In this embodiment, each of the first passive component 370 and the second passive component 480 may be implemented by a capacitive component. Please note that the calibrating system 40 having two capacitive components to form a current loop is especially suitable for the test signal with magnetic field coupling characteristics of a loop.

As one can see from the figures, by using the calibrating system 20, 30, or 40 shown in FIG. 2, FIG. 3, and FIG. 4, the near-field factor L(ω) can be precisely predicted. Therefore, the near-field probe effect(s) corresponding to the probe 210 can be removed without affecting the measured result of the test board 230 when a non-contact measurement is adopted on the measuring equipment 200.

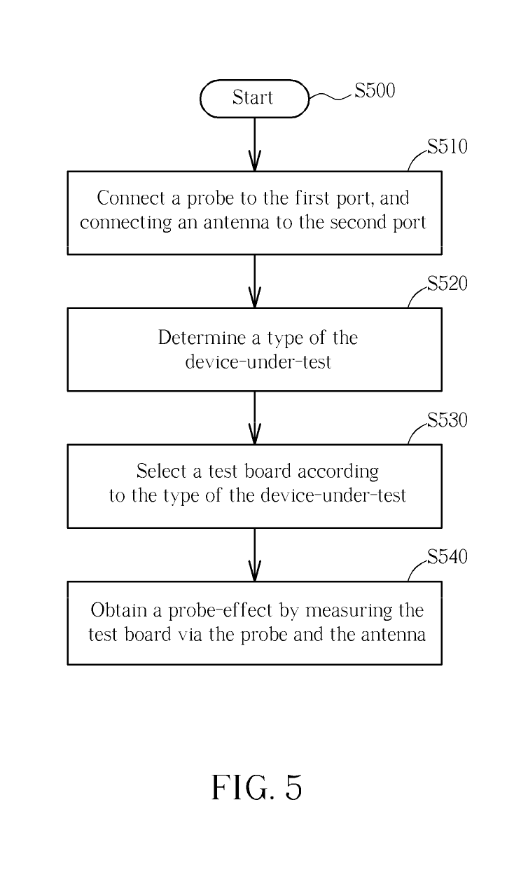

FIG. 5 is a flowchart illustrating a method for probe-effect cancellation of a measuring equipment according to an exemplary embodiment of the present invention. In one embodiment, the measuring equipment has a first port and a second port for measuring a device-under-test. Please note that the following steps are not limited to be performed according to the exact sequence shown in FIG. 5 if a roughly identical result can be obtained. The method includes the following steps:

Step S500: Start.

Step S510: Connect a probe to the first port, and connecting an antenna to the second port.

Step S520: Determine a type of the device-under-test.

Step S530: Select a test board according to the type of the device-under-test.

Step S540: Obtain a probe-effect by measuring the test board via the probe and the antenna.

As how each element operates can be readily known by collocating the steps shown in FIG. 5 together with the elements shown in FIG. 2 or FIG. 3, further description is therefore omitted here for brevity.

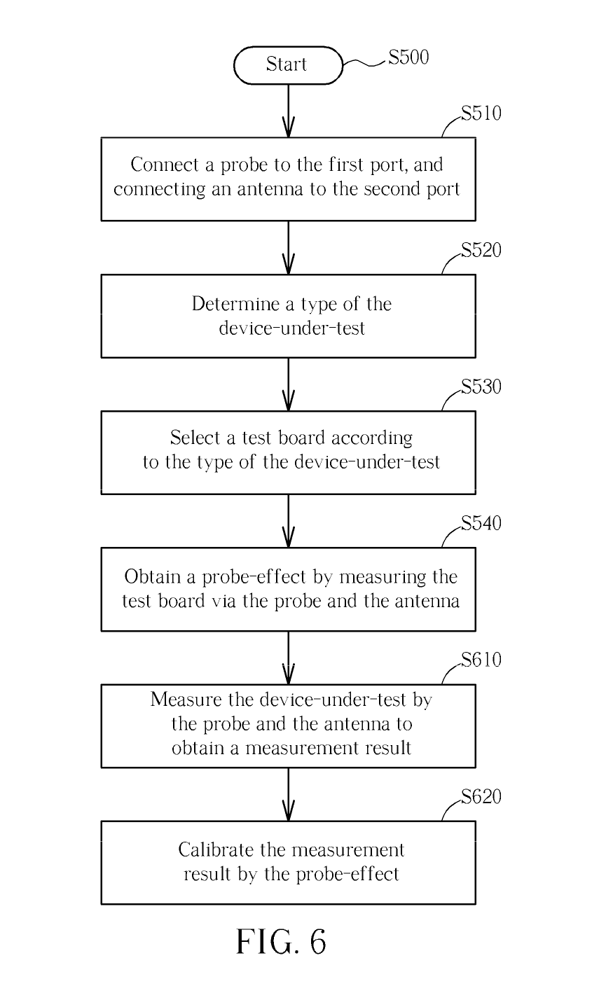

FIG. 6 is a flowchart illustrating a method for probe-effect cancellation of a measuring equipment according to another exemplary embodiment of the present invention. Please note that the following steps are not limited to be performed according to the exact sequence shown in FIG. 6 if a roughly identical result can be obtained. The method includes the following steps:

Step S500: Start.

Step S510: Connect a probe to the first port, and connecting an antenna to the second port.

Step S520: Determine a type of the device-under-test.

Step S530: Select a test board according to the type of the device-under-test.

Step S540: Obtain a probe-effect by measuring the test board via the probe and the antenna.

Step S610: Measure the device-under-test by the probe and the antenna to obtain a measurement result.

Step S620: Calibrate the measurement result by the probe-effect.

The steps shown in FIG. 6 are similar to that shown in FIG. 5, and the difference between them is that: the flowchart shown in FIG. 6 further includes the steps S610 and S620. As how each element operates can be readily known by collocating the steps shown in FIG. 6 together with the elements shown in FIG. 4, further description is therefore omitted here for brevity.

Please note that, the steps of the abovementioned flowcharts are merely practicable embodiments of the present invention, and in no way should be considered to be limitations to the scope of the present invention. These methods can include other intermediate steps or several steps can be merged into a single step without departing from the spirit of the present invention.

In summary, exemplary embodiments of the present invention provide a measuring equipment and a related method for probe-effect cancellation of a measuring equipment. By adopting the calibrating mechanism (including the measuring equipment of the calibrating system and the calibrating method) disclosed in the present invention, the near-field factor L(ω) can be precisely predicted. Therefore, the near-field probe effect(s) corresponding to the probe can be removed without affecting the measured result of the test device when a non-contact measurement is adopted on the vector network analyzer. In addition, the measuring equipment can be especially suitable for all conditions, such as a test signal with a resistive signal transmission, a test signal with a capacitive signal transmission, or a test signal with a magnetic field coupling characteristic of a loop.

Those skilled in the art will readily observe that numerous modifications and alterations of the device and method may be made while retaining the teachings of the invention.

What is claimed is:

1. A measuring equipment, comprising:
a first port and a second port;
a probe connected to the first port;
an antenna connected to the second port; and
a test board, corresponding to a type of a device-under-test;
wherein a probe-effect is obtained by measuring the test board via the probe and the antenna.

2. The measuring equipment of claim 1, wherein the device-under-test is measured by probe and the antenna to obtain a measurement result, and the measurement result is calibrated according to the probe-effect.

3. The measuring equipment of claim 1, wherein the type of the device-under-test is one of a capacitive type, a resistive type and a power/ground type.

4. The measuring equipment of claim 3, wherein the test board comprises a transmission line without termination if the device-under-test is of the capacitive type.

5. The measuring equipment of claim 3, wherein the test board comprises a transmission line with termination if the device-under-test is of the resistive type.

6. The measuring equipment of claim 3, wherein the test board comprises a transmission lines and a decoupling capacitor forming a current loop, if the device-under-test is of the power/ground type.

7. The measuring equipment of claim 3, wherein the test board comprises two transmission lines and two decoupling capacitors forming a current loop.

8. The measuring equipment of claim 1, wherein the probe and the antenna do not directly contact the test board and the device-under-test.

9. A method for probe-effect cancellation of a measuring equipment, the measuring equipment having a first port and a second port for measuring a device-under-test, the method comprising:
connecting a probe to the first port, and connecting an antenna to the second port;
determining a type of the device-under-test;
selecting a test board according to the type of the device-under-test; and
obtaining a probe-effect by measuring the test board via the probe and the antenna.

10. The method of claim 9, further comprising:
measuring the device-under-test by the probe and the antenna to obtain a measurement result; and
calibrating the measurement result by the probe-effect.

11. The method of claim 9, wherein the type of the device-under-test is one of a capacitive type, a resistive type and a power/ground type.

12. The method of claim 11, wherein the test board comprises a transmission line without termination if the device-under-test is of the capacitive type.

13. The method of claim 11, wherein the test board comprises a transmission line with termination if the device-under test is of the resistive type.

14. The method of claim 11, wherein the test board comprises a transmission lines and a decoupling capacitor forming a current loop, if the device-under-test is of the power/ground type.

15. The method of claim 11, wherein the test board comprises two transmission lines and two decoupling capacitors forming a current loop, if the device-under-test is of the power/ground type.

16. The method of claim 9, wherein the probe and the antenna do not directly contact the test board and the device-under-test.
